(19) United States
(12) Patent Application Publication
(10) Pub. No.: US 2013/0042902 A1
(43) Pub. Date: Feb. 21, 2013

(54) HYBRID SOLAR ENERGY CONVERSION SYSTEM WITH PHOTOCATALYTIC DISINFECTANT LAYER

(71) Applicants: Jun Yang, London (CA); Leo Lau, Kowloon (HK); Zhifeng Ding, London (CA)

(72) Inventors: Jun Yang, London (CA); Leo Lau, Kowloon (HK); Zhifeng Ding, London (CA)

(73) Assignee: THE UNIVERSITY OF WESTERN ONTARIO, London, ON (CA)

(21) Appl. No.: 13/577,156

(22) PCT Filed: Feb. 9, 2011
(86) PCT No.: PCT/CA11/50072

§ 371 Date: Oct. 4, 2012

Related U.S. Application Data
(60) Provisional application No. 61/302,627, filed on Feb. 9, 2010.

(51) Int. Cl. H01L 31/058

(52) U.S. Cl. 136/248

(57) ABSTRACT

The present invention provides a hybrid solar energy conversion system in which a working fluid is made to flow between an internal photovoltaic array and a transparent top layer, where the working fluid is disinfected by a photocatalytic disinfectant layer provided on a light transmitting surface contacting the working fluid. The working fluid is further contacted with the photovoltaic array for the absorption of heat, and the absorbed heat is extracted via an external heat extraction device such as a water tank or a heat exchanger. Accordingly, the present invention provides an improved solar energy conversion system providing both electrical and thermal power, and further utilizing a portion of the solar spectrum for the photocatalytic disinfection of the working fluid.

### CROSS-REFERENCE TO RELATED APPLICATION

This application claims priority to U.S. Provisional Application No. 61/302,627, titled “HYBRID SOLAR ENERGY CONVERSION SYSTEM WITH PHOTOCATALYTIC DISINFECTANT LAYER” and filed on Feb. 9, 2010, the entire contents of which are incorporated herein by reference.

### FIELD OF THE INVENTION

This invention relates to solar energy conversion devices. More particularly, the present invention relates to hybrid solar energy conversion devices providing both electricity and heat as well as other solar enabled functions such as photocatalytic disinfection.

### BACKGROUND OF THE INVENTION

Solar energy conversion devices, in particular photovoltaic arrays, continue to deliver improved efficiency and reduced cost each year. However, the modest theoretical limit to the conversion efficiency of photovoltaic cells underscores the fact that a significant portion of the absorbed solar energy is wasted in heat in even the most efficient devices, and, in turn, the absorbed heat lowers the photovoltaic efficiency of the PV cells.

To improve upon the efficiency of photovoltaic solar cells, many prior art devices and systems have attempted to provide hybrid solar energy conversion systems that extract heat absorbed by the photovoltaic cells. For example, U.S. Pat. No. 5,589,006 discloses a hybrid solar cell in which heat generated by the solar cell is used to heat air passing beneath the solar cell. Similarly, U.S. Patent Application No. 20090173375 teaches a hybrid solar conversion system in which air is flowed and heated over slats coated with a photovoltaic material.

U.S. Pat. No. 6,472,593 describes a hybrid solar system in which a thin film solar cell is directly contacted with a medium to be heated. U.S. Patent Application No. 20040055631 discloses a hybrid system in which a photovoltaic array absorbs short wavelength radiation for conversion into electrical energy, where longer wavelength radiation is transmitted to a thermal collector.

U.S. Patent Application No. 20080302357 provides an improved hybrid solar energy collector comprising a Cu(InₓGa₁₋ₓ)Se₂ (CIGS) photovoltaic energy collector, the photovoltaic energy collector being thermally coupled to an energy absorbing working fluid casing for flowing heat out to heat sink. The solar module is cooled by the working fluid transferring unproductive heat away from the photovoltaic array and into an exterior heat sink via the cooling fluid circuit. Similarly, U.S. Patent Application No. 20090065046 describes a system for a retrofitting a photovoltaic energy collector, by coupling a thermal energy absorbing working fluid casing for flowing heat out to a heat sink.

International Patent Application WO2005121030,filed by Blanco et al., provides an improved hybrid device for the simultaneous generation of electricity, the extraction of heat, and the photocatalytic decontamination of water. Blanco et al. disclose flowing water over the surface of a photovoltaic array and within a photocatalytic reactor, where the water is sterilized by the action of a photocatalytic substance provided as a suspension within the water.

Unfortunately, the aforementioned hybrid solar energy conversion systems do not provide for the efficient extraction of heat, the convenient photocatalytic disinfection of the working fluid, and the effective prevention of growth of biofilm on the inner surfaces of the system.

### SUMMARY OF THE INVENTION

Embodiments of the present invention provide improved hybrid solar conversion devices, systems and methods, in which the limitations of known hybrid systems by providing a hybrid solar energy conversion system that is adapted to provide efficient extraction of heat in addition to electricity from a solar array using a working fluid that is disinfected by a photocatalytic layer adhered on a light transmitting surface within the device. Unlike prior art systems, the embodiments disclosed herein include fluid conduits both above and below the photovoltaic array for the improved extraction of heat. By providing a dedicated heat extraction conduit below the photovoltaic array, the heat extraction is substantially increased. The provision of the heat extraction conduit below the array allows the heat extraction portion of the device to be configured without impacting the optical performance of the system, such as changing the geometry or adding a more heat conducting material.

In selected embodiments, the photocatalytic material is provided on a solid phase, and preferably coats an inner surface of the conduit. This solves several problems associated with hybrid photovoltaic and photocatalytic systems. In particular, by providing the photocatalytic material as a solid phase coating on the inner surfaces of the conduit, the growth of biofilms may be prevented or reduced. Furthermore, the use of a solid phase coating instead of a suspension avoids problems and inconveniences associated with filtering the working fluid for the removal of photocatalytic particles.

In a first aspect, there is provided a hybrid solar energy conversion device comprising: a housing having a transparent top layer; a photovoltaic array enclosed within the housing, wherein light incident on and transmitted through the top layer illuminates the photovoltaic array and produces electricity and heat; a first fluid conduit formed between the top layer and an upper surface of the photovoltaic array; a photocatalyst provided within the first fluid conduit for treating a working fluid flowing in the first fluid conduit; and a second fluid conduit provided beneath the array, the second fluid conduit in flow communication with the first fluid conduit, wherein the second fluid conduit is configured to provide thermal contact between the working fluid and the photovoltaic array for extracting heat from the photovoltaic array; and an inlet port and an outlet port in flow communication with the first fluid conduit and the second fluid conduit.

The photocatalyst may comprise a coating adhered to a light transmitting surface within the first fluid conduit. The photocatalyst may be adhered to at least a portion of an inner surface of the first fluid conduit.

A heat sink may be affixed to a back side of the array, wherein the heat sink is positioned to contact the working fluid in the second fluid conduit.

The photocatalyst may comprise nanoscale titania, and may also comprise glass fibers coated with nanoscale titania.

The top layer may comprise at least two vacuum sealed transparent panes. An additional photocatalyst may be adhered to an external surface of the top layer for self cleaning. A spectral bandwidth of the photocatalyst may comprise at least a portion of the ultraviolet spectrum. One or more surfaces of the top layer may comprise an anti-reflective coating. At least a portion of the housing may be thermally insulated.

One or more of the photovoltaic arrays may comprise monocrystalline silicon, polycrystaliline silicon, silicon, cadmium telluride, copper-induim selenide, copper indium gallium selenide, gallium arsenide, dye-sensitized, polymer solar cells, and Cu(InₓGa₁₋ₓ)Se₂ (CIGS).

The working fluid may comprise a liquid such as water, or may be a gas, such as air.

The photocatalyst may comprise a suspension of photocatalytic particles within the working fluid.

In another aspect, there is provided a hybrid solar energy conversion system comprising one or more of the hybrid solar energy conversion devices as described above, wherein the devices are connected in series or in parallel.

In yet another aspect, there is provided a hybrid solar energy conversion system comprising a hybrid solar energy conversion device in which the working fluid is a gas, and a fan for providing a flow of the gas through the device.

In still another aspect, there is provided a hybrid solar energy conversion system comprising a hybrid solar energy conversion device as described, the system further comprising: a vessel for storing the working fluid, wherein the vessel is external to the hybrid solar energy conversion device and the inlet port and the outlet port are in flow communication with the vessel; wherein the system is configured to circulate the working fluid between the vessel and the device.

The system may further comprise: an inlet line connecting the inlet port to a first location within the vessel; and an outlet line connecting the outlet port to a second location within the vessel. The first location may be above the second location, and wherein the system is configured to circulate the working fluid under passive convection.

The system may further comprise a flow means for circulating the working fluid, where the flow means may be a pump.

The system may further comprise a heat extraction means for extracting heat from the working fluid, where the heat extraction means may be external to the housing. The heat extraction means may be a heat exchanger.

The device may be oriented at an angle relative to a horizontal plane, where the system is configured to circulate the working fluid by convection generated within the device, and where the device may be positioned adjacent to the vessel, where the inlet port and the outlet port positioned at an upper position on the device and are connected to the vessel.

In another aspect, there is provided a hybrid solar energy conversion device comprising: a housing having a transparent top layer; a photovoltaic array enclosed within the housing, wherein light incident on and transmitted through the top layer illuminates the photovoltaic array and produces electricity and heat; a first fluid conduit formed between the top layer and an upper surface of the photovoltaic array; a photocatalyst provided within the first fluid conduit for disinfecting a working fluid flowing in the first fluid conduit; and a second fluid conduit provided beneath the array, the second fluid conduit in flow communication with the first fluid conduit, wherein the second fluid conduit is configured to provide thermal contact between the working fluid and the photovoltaic array for extracting heat from the photovoltaic array; and a heat exchanger for extracting heat from the working fluid.

In yet another aspect, there is provided a method of converting solar energy, the method comprising the steps of: providing a hybrid solar energy conversion device as described above; flowing the working fluid into the inlet port; extracting d working fluid from the outlet port; and extracting electrical energy from the device.

The method may further comprise the step of extracting heat from the working fluid.

The method may further comprise the step of controlling a conversion efficiency of the photovoltaic array by a varying a property of the working fluid, where the property may be varied in response to a measured temperature, wherein the measured temperature is related to an efficiency of the photovoltaic array, and where the property may be one or more of a flow rate of the working fluid and an initial temperature of the working fluid.

A further understanding of the functional and advantageous aspects of the invention can be realized by reference to the following detailed description and drawings.

### BRIEF DESCRIPTION OF THE DRAWINGS

The embodiments of the present invention are described with reference to the attached figures, wherein:

FIG. 1 shows (a) a hybrid solar energy conversion device incorporating an upper conduit for disinfecting a working fluid having a suspension of a photocatalyst, and (b) an improved device in which the photocatalyst is adhered to a solid light transmitting surface that is in contact with the working fluid.

FIG. 2 illustrates a hybrid device in which the working fluid flows in a serpentine path.

FIG. 3 shows an improved hybrid solar energy conversion system in which the working fluid flows from an upper photocatalytic conduit to a lower thermal transfer conduit.

FIG. 4 illustrates an embodiment in which a hybrid solar device passively heats fluid stored in a tank.

FIG. 5 illustrates a configuration in which two hybrid devices are connected in series.

FIG. 6 shows a preferred embodiment of the system incorporating several functional layers, where the working fluid is circulated to a storage tank.

### DETAILED DESCRIPTION OF THE INVENTION

Generally speaking, the systems described herein are directed to hybrid solar energy conversion devices incorporating photocatalytic disinfection of a working fluid and improved heat extraction. As required, embodiments of the present invention are disclosed herein. However, the disclosed embodiments are merely exemplary, and it should be understood that the invention may be embodied in many various and alternative forms. The Figures are not to scale and some features may be exaggerated or minimized to show details of particular elements while related elements may have been eliminated to prevent obscuring novel aspects. Therefore, specific structural and functional details disclosed herein are not to be interpreted as limiting but merely as a basis for the claims and as a representative basis for teaching one skilled in the art to variously employ the present invention. For purposes of teaching and not limitation, some illustrated embodiments are directed to Cu(InₓGa₁₋ₓ)Se2-based hybrid solar energy conversion devices incorporating a photocatalytic layer for the disinfection of a working fluid and improved heat extraction.

As used herein, the terms, “comprises” and “comprising” are to be construed as being inclusive and open ended, and not exclusive. Specifically, when used in this specification including claims, the terms, “comprises” and “comprising” and variations thereof mean the specified features, steps or components are included. These terms are not to be interpreted to exclude the presence of other features, steps or components.

As used herein, the terms “about” and “approximately”, when used in conjunction with ranges of dimensions of particles, compositions of mixtures or other physical properties or characteristics, are meant to cover slight variations that may exist in the upper and lower limits of the ranges of dimensions so as to not exclude embodiments where on average most of the dimensions are satisfied but where statistically dimensions may exist outside this region. It is not the intention to exclude embodiments such as these from the present invention.

As used herein, the term “exemplary” means “serving as an example, instance, or illustration,” and should not necessarily be construed as preferred or advantageous over other configurations disclosed herein.

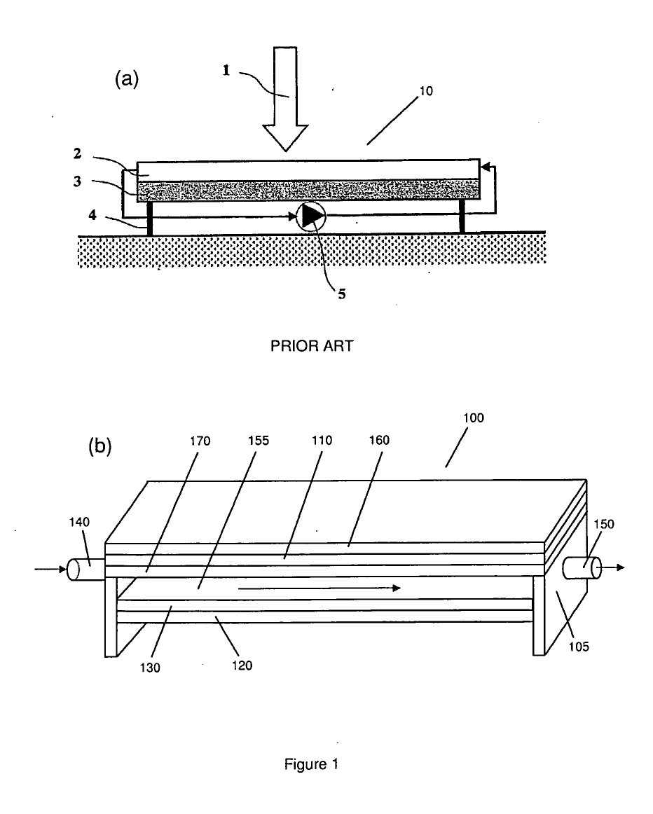

FIG. 1(a) illustrates a hybrid photocatalytic and photovoltaic device known in the art, as taught by Blanco et al. (International Patent Application WO2005121030). Photovoltaic array 3 generates electricity through photovoltaic conversion of incident sunlight 1. Conduit 2 is formed on top of photovoltaic layer, and provides a flow path for water from one side of the device to another. A photocatalytic substance, such as iron or titania, is added to the water prior to flowing it through the system to form a suspension. As the water containing the photocatalytic suspension flows through conduit 2, it is photocatalytically disinfected by sunlight. The assembly is supported by structures 4 for orientating the array, and the water is recirculated within the system using pump 5.

Referring now to FIG. 1(b), an improved device 100 is shown in which the photocatalytic layer need not be provided as a suspension within the working fluid. The device is shown comprising a fluid-tight external housing 105 having a transparent top layer 110 and a photovoltaic array 120 supported within housing 105. The photovoltaic array 120 is electrically isolated from the working fluid by a transparent photocatalytic and electrically insulating top surface like a TiO₂ coated glass 130. A fluid conduit 155 is formed between the top layer 110 and photovoltaic array 120, where a working fluid flows laterally from inlet port 140 to outlet port 150. Top layer 110 may have an anti-reflective coating formed on one or more of its surfaces (shown at 160 as an example configuration). Top surface 130 of the photovoltaic array 120 is preferably formed from a transparent material that efficiently transfers heat to the working fluid, such as glass and indium tin oxide. External electrical contacts, such as standard electrical connectors that are internally connected to the array (not shown) provide locations where converted electrical energy may be extracted from the system. External housing, in addition to being fluid-tight, is preferably also thermally insulating in order to minimize thermal losses. For example, transparent top layer 110 may comprise dual planar spaced transparent window layers with an intermediate vacuum region for thermal insulation.

A photocatalytic disinfectant layer 170 is provided on the inner surface of transparent top layer 110, where it interacts with incident sunlight to catalyze the disinfectant treatment of the working fluid. Alternatively or additionally, the photocatalytic layer may be provided on any internal light transmitting surface that comes into contact with the working fluid. In other non-limiting embodiments, the photocatalyst may be adhered to the upper surface 120 of the solar array. A layer of photocatalyst disinfectant may also optionally be provided on the external (top) surface of the top layer for self-cleaning and resisting the growth of organisms on the external transmissive surface of housing 105.

Generally speaking, the photocatalyst may be adhered to any transparent and light transmitting solid phase surface and may form a coating on any or all of the internal surface of conduit 155. In another example, the photocatalytic layer may be provided on any internal surface of a transparent channel or tubular structure defining a fluid flow channel. In another embodiment, the channel may be comprise a solid phase material other than a coating, such as, for example, a porous and transparent material that offers enhanced surface area for contacting the working fluid with the photocatalytic medium.

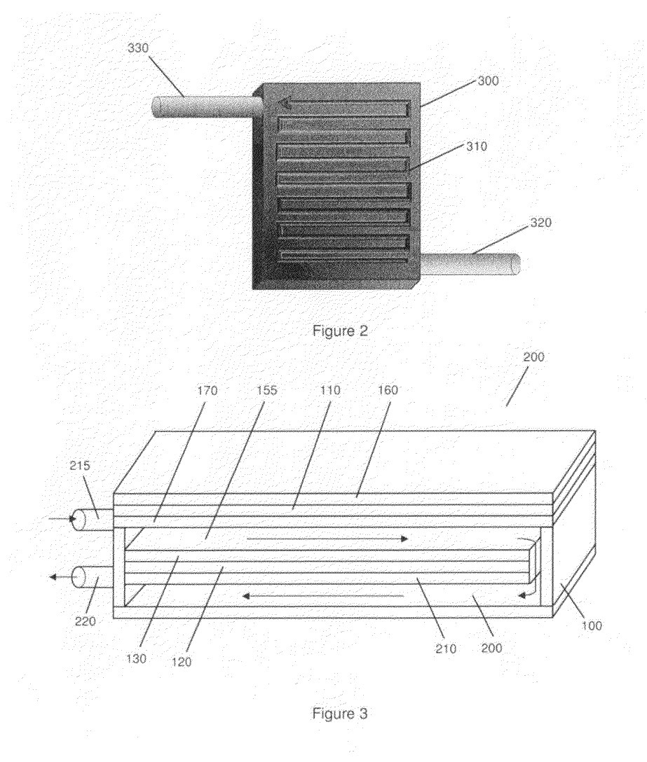

FIG. 2 shows a hybrid integrated photocatalytic device incorporating a single flow conduit between the solar array and the transparent top surface, where the conduit traverses above the photovoltaic array in a serpentine network. Fluid enters serpentine conduit 310 through inlet 320 and exits through outlet 330. Serpentine conduit 310 is preferably a transparent hollow structure, such as a tube or channel, and a photocatalytic surface layer is coated on at least a portion of the internal surface of the conduit to disinfect the working fluid while it is transported across the device.

Referring now to FIG. 3, an embodiment is illustrated that provides improved photocatalytic, photovoltaic and thermal performance. Device 200 further comprises a second conduit 205 positioned beneath photovoltaic array 120 for improved and efficient heat extraction. Under active or passive fluid flow, as discussed in greater detail below, working fluid enters through inlet 215, flows through first conduit 155, where it is disinfected via a photocatalytic process, and subsequently flows into a second fluid conduit 180 provided below the photovoltaic array.

Within second conduit 205, the working fluid comes into thermal contact with the back side of the array 120 via thermally conductive layer 210. Thermally conductive layer 210 may be a planar substrate having a high thermal conductivity and/or thermal mass, and may be further contacted with a heat sink (not shown). Preferably, the fluid is provided to the inlet at a temperature less than the temperature of layer 150.

Unlike systems known in the art, the embodiment illustrated in FIG. 3 enables the efficient extraction of thermal energy from the photovoltaic array 120 in a dedicated region that is not subject to the constraints imposed on the top layer—namely the requirement for optically transparent materials. As a result, materials with suitable thermal conductivity and/or thermal mass may be selected for the efficient extraction of heat. This improved design provides numerous benefits to overall system performance due to the synergistic relationship between the different elements of the design. Unlike existing designs, the present system provides a solution for the efficient generation of electricity, the efficient extraction of heat, and the efficient disinfection or decontamination of the working fluid. By enabling the thermal extraction to be carried out substantially beneath the photovoltaic array, a greater amount of heat extraction may be achieved, thus lowering the operating temperature of the photovoltaic array and increasing the array's overall efficiency. The flexible nature of the design also allows the materials forming the layers above the photovoltaic array to be selected for optimal transparency, also increasing the overall system performance.

While the above embodiments disclose exemplary systems in which the photocatalyst is provided as an internal component of the system in the form of a coating on a solid phase, it is to be understood that a suspension of photocatalyst particles may also be employed to support disinfection or decontamination of the working fluid. For example, in the embodiment illustrated in FIG. 3, the photocatalyst layer may be removed and the photocatalyst may flow through the system in the form of suspended particles. As noted above, however, it is preferred that that the photocatalyst be provided as an immobilized solid phase in order to avoid the need to separate the photocatalyst from the working fluid in a separate processing step.

In a preferred embodiment, the photocatalyst disinfectant layer utilizes the UV spectrum and may further utilize a portion of the visible spectrum. Accordingly, the device provides an improved hybrid approach to solar energy conversion in which the different components of the solar spectrum are used with high efficiency. The visible spectrum, and portions of the UV and infrared spectrum are utilized for electrical conversion. The infrared, and portions of the UV and visible spectrum are used to produce heat. The UV, and optionally portions of the visible spectrum, are employed for the photocatalytic disinfection of the working fluid.

Preferably, the photocatalyst is a nanoscale thin film of titanium dioxide (titania), metal or nonmetal-doped titanium dioxide. In a more preferable embodiment, the photocatalyst disinfectant layer is a nanoscale titania thin film formed on the surface of glass fibers to significantly increase photocatalytic efficiency. Nanoscale titania is preferred for its ability to photocatalyze the disinfection of water using the ultraviolet portion of the solar spectrum. With metal such as Ag, Fe, Al, Mn or nonmetal (such as C, N, F, S) doped titanium dioxide, the effective portion of the solar spectrum is extended to part of blue light. This provides excellent utilization of the solar spectrum, where ultraviolet light is used for disinfection, and visible and infrared light is employed for the generation of electrical and thermal power.

Titanium dioxide (TiO₂) is the most widely used photocatalyst among all photocatalytic compounds, because TiO₂, a FDA-approved chemical, is inexpensive, biologically and chemically stable, and corrosion-resistive. Upon absorption of photons with energy equal to or larger than the band gap energy of TiO₂ photocatalyst, electron and hole pairs are generated. Subsequently when holes or electrons react with H₂O or O₂, hydroxyl and superoxide radicals are produced, which are strong oxidizing species. These radicals react with chemicals adsorbed on the photocatalyst surface, and decompose them to form more environmentally-acceptable products like CO₂ and H₂O.

The titania thin films used in embodiments of this invention are transparent and preferably of nanoscale dimensions. Titania solution may be first synthesized by a sol-gel method, and then thermally treated to a temperature of around 500° C., resulting in nanoscale titania thin films with a mesoporous morphology. In a preferred embodiment, the thickness of titania thin film is approximately around one hundred nanometers.

In alternative embodiments, metal (Ag, Fe, Al, Mn) doped TiO₂ nanomaterials, nonmetal (C, N, F, S) doped TiO₂ nanomaterials, or metal-nonmetal-co-doped TiO₂ can also be used to expand photocatalysts' effective spectral bandwidth to at least a portion of the blue spectral region. Alternatively, metal oxides such as ZnO can be used as photocatalysts.

The integration of a photocatalytic coating layer on an inner surface of the upper conduit is particularly advantageous in decontaminating the working fluid from a wide variety of microorganisms and unwanted chemical constituents. However, the photocatalytic coating is also beneficial as a preventative coating that resists the growth of biofilms that can otherwise foul the internal surface of the conduit. Such biofilms also pose health risks as they are known to form with pathogenic bacteria such as legionella.

This is an important advantage, as biofilms that form on light transmitting internal surfaces of the device can lead to significant reductions in optical transmittance and hence overall system performance. Biofilms can also cause reduced thermal conductivity and thus indirectly affect system performance as a result of insufficient cooling of the photovoltaic array, and ineffective extraction of heat for other uses. The preventative aspect of the solid phase photocatalytic coating within the upper conduit therefore can play an important role in contributing to improved overall performance. It is further noted that hydroxyl ions formed as a result of the photocatalytic process (or other decontaminating species) may flow with the working fluid to the other portions of the system in fluid communication with the upper conduit (such as the lower conduit, the input ports, an external storage vessel, and external delivery or supply lines), where they can also act as decontaminants.

The working fluid may be any liquid that can be disinfected by the photocatalytic layer. In a preferred embodiment, the working fluid is water. In another non-limiting embodiment, the working fluid is ethanol.

While the preceding embodiments involve the use of liquids such as water as the working fluid, it is to be understood that the working fluid is not limited to liquids, and may instead be provided in the form of a gas. In a preferred embodiment, the gas is air, and the humidity of the gas may be controlled to prevent to the formation of a condensate within the system. Generally speaking, a gas employed as a working fluid should not be susceptible to photocatalytic degradation via the photocatalyst (for example, some hydrocarbons may be photodegraded by the photocatalyst).

In embodiments in which gas is provided as the working fluid, the photocatalytic coating provided within the conduit may be employed for the decontamination, purification or disinfection of the gas, for example, for the elimination of harmful chemicals, or airborne microorganisms such as bacteria, spores, viruses. The gas flow may be provided by natural convection, or via a forced air system. In one embodiment, the gas flow may be maintained and/or controlled by a fan, where the fan may be optionally powered by electricity generated by the photovoltaic array.

While the above embodiment includes a substantially planar fluid conduit between the top layer 110 and the photovoltaic array 120, it will be apparent to those skilled in the art that a wide variety of flow geometries are encompassed by the scope of the disclosed embodiments. For example, in a non-limiting embodiment, working fluid may flow between the top layer 110 and the photovoltaic array 120 in transparent tubes or channel structures that transmit at least a portion of the incident sunlight, where the photocatalytic disinfectant is adhered on an internal surface of the structures to disinfect the working fluid. In another non-limiting example, the second conduit may comprise a tubular or channel structure in thermal contact with the back surface of the photovoltaic array, for example, in a serpentine pattern to obtain increased thermal transfer of absorbed heat.

In one embodiment, the rate of cooling of the photovoltaic array may be controlled in order to obtain sufficiently high overall system efficiency. For example, it is well known that the optical to electrical conversion efficiency of photovoltaic arrays declines substantially with increasing temperature. As a result, it is generally preferable to operate a photovoltaic array below a temperature of approximately 50 to 60° C. Accordingly, the flow rate of the working fluid, or the initial temperature of the working fluid, may be controlled in order to achieve a desired photovoltaic operating temperature and/or conversion efficiency. This may be achieved, for example, by locally measuring the temperature of the working fluid in the vicinity of the photovoltaic array (or the temperature of a surface or object in thermal contact with the photovoltaic array), and employing the temperature as an input to a feedback loop.

As noted above, in embodiments in which the working fluid is a liquid, the working fluid may be flowed through the device due to a passive or actively formed pressure gradient. In one embodiment, the pressure gradient is provided by an external active system such as a pump, where the power to run the active system may be provided by electricity generated by the photovoltaic array. In another embodiment, the pressure gradient is provided by hydrostatic forces. In yet another embodiment, the pressure gradient is provided by convective forces such as natural convective pressure.

In addition to direct use of the heated working fluid, the heat absorbed by the working fluid may be extracted from the system using an external heat extraction device or system. In a preferred embodiment, the working fluid flows out of the housing outlet after flowing through the second conduit 205, where it is sent to an external heat extraction device. Non-limiting examples of heat extraction devices include a water tank and a heat exchanger.

In one embodiment in which the heat extraction device is a fluid tank, working fluid heated by the second conduit 205 enters the fluid tank at an upper location where the temperature of the water is higher, and is extracted and recirculated to the hybrid device inlet from a lower location and thereby at a lower temperature. Heated water may be extracted for use from the system, and is preferably replenished by a fluid source feeding the bottom of the tank.

In yet another embodiment, the working fluid may be contained and recirculated within housing 105, and contacted with a secondary working fluid in an internal heat exchanger provided within housing 105 (for example, with the second flow path 205 shown in FIG. 3 beneath the photovoltaic array, after the working fluid has absorbed heat from the photovoltaic array). The internal heat exchanger may comprise a flow path for a second working fluid, in which second working fluid is in thermal contact with the first working fluid. The secondary working fluid, after having been heated by internal heat exchanger, is subsequently flowed out of an outlet in housing 105, where it is externally delivered and cooled. The cooled secondary working fluid then re-enters housing 105 and is again heated by the internal heat exchanger. In one embodiment, one working fluid may be vaporized after heated. It will be apparent to those skilled in the art that a wide variety of heat exchanger formats and geometries may be employed.

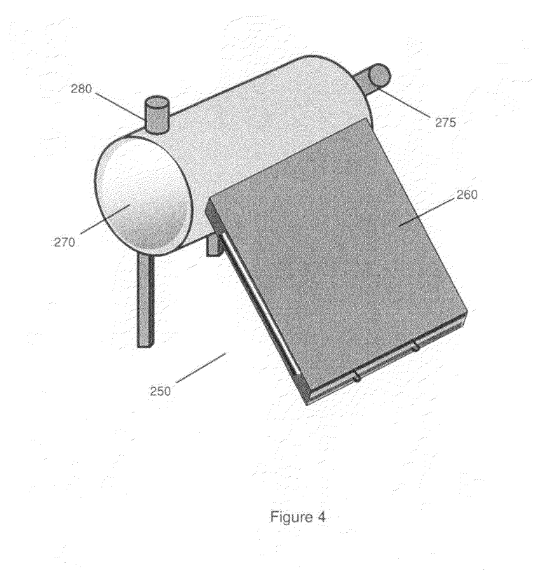

FIG. 4 illustrates a passive system 250 in which the hybrid solar device 260 is attached directly to the side of a tank 270. Prior to using the system, a fluid flow device such as a pump (not shown) infuses the working fluid into tank 260. For example, if water is used as the working fluid, the water tank can be directly connected to the local water supply through inlet 275. During operation, natural convection causes the working fluid to circulate and repeatedly flow through the first and second conduits of the hybrid device 260. Hot or warm working fluid may be extracted from outlet 280 at the top of tank 270. This design enables the system being operated automatically without any external energy input except solar energy due to natural convection.

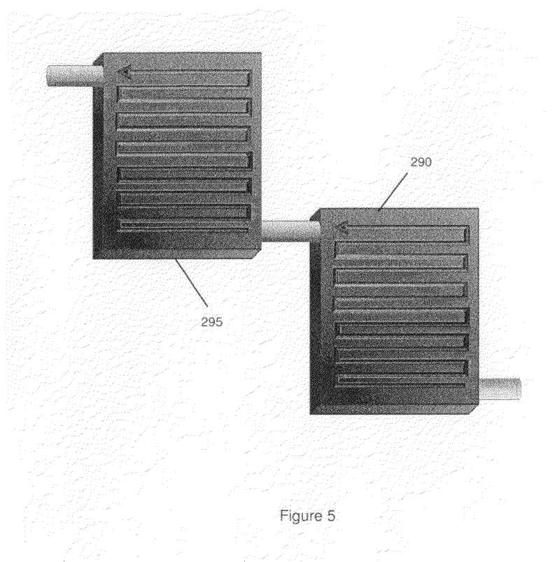

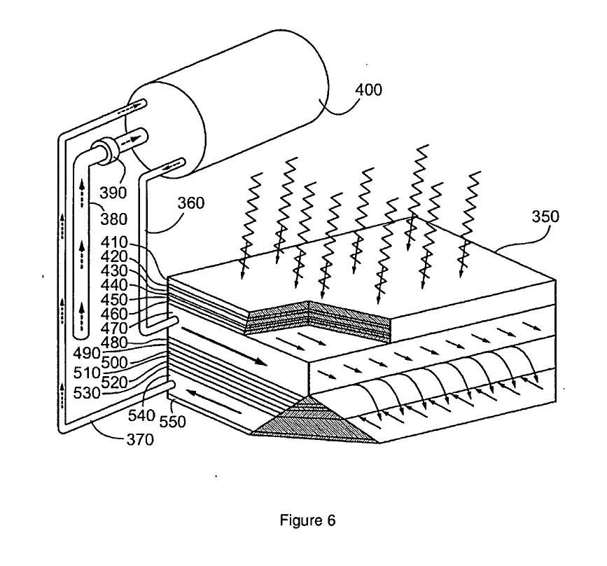

Although the aforementioned discussion has focused on a system incorporating a single hybrid device, embodiments of the invention include multiple devices connected in series or in parallel. In one embodiment, a system is provided that incorporates multiple devices connected in series, with the outlet of one device connected to the inlet of another device. Such an embodiment is illustrated in FIG. 5, where a working fluid first flows through first hybrid device 290 and then into second hybrid device 295. This arrangement can be useful when it is desirable to increase the final temperature of the working fluid. The optimal number of serial devices will depend on the initial working fluid temperature, the amount of solar heat absorbed by each device, and the degree of thermal contact within each device. In one embodiment, devices of different size may be used to optimize the heat transfer and cooling of each photovoltaic array. In yet another embodiment, multiple devices may be connected in parallel. This embodiment may be useful when it is desirable to increase the net flow rate of working fluid within the system.

It is also to be understood that the hybrid device may be operated in a pass-through configuration that does not require or involve the re-circulation of working fluid through the device. For example, the hybrid device may be used in a single-pass approach to incrementally heat working fluid for a particular process.

In another embodiment, the hybrid device may be assembled as a retrofit to an existing solar array device. For example, the thermally conductive solar array assembly for the hybrid device may be obtained from an existing solar array that has been retrofitted to provide for heat transfer to a working fluid (and sealed accordingly). For example, the backing material of a pre-existing solar array may be removed and replaced with a thermally conductive layer if such a layer was not originally included in the device. Alternatively or additionally, the top transparent surface of an existing solar array may be coated with a photocatalytic layer and subsequently incorporated into the hybrid device. Other methods, such as those disclosed in U.S. Patent Application No. 20090065046, which is incorporated by reference herein in its entirety, may be employed.

Unlike known hybrid solar energy conversion systems, the embodiments disclosed herein provide an inventive system integrating several state-of-the-art green technologies, namely solar-electricity, solar-thermal-water-heating, and solar-cleaning into a 3-in-1 solar energy conversion system. Such a system is expected to be suitable for design at a cost that would allow users (such as home-owners and industrial users) to affordably and easily participate in the emerging green revolution.

While the photovoltaic array 120 is not intended to be limited to any specific material composition, in one embodiment, the photovoltaic array is a Cu(InₓGa₁₋ₓ)Se₂ (CIGS) array. CIGS solar arrays are well suited to embodiments disclosed herein due to their tendency to absorb significant amounts of heat, which, if not removed, can impair the cell efficiency. Accordingly, the use of a CIGS solar array in the preceding embodiments provides the dual benefit of (a) increasing the efficiency of the CIGS array due to thermal extraction and management in the system and (b) providing a secondary energy source to the user in the form of extracted heat. A preferred structure for a CIGS-based solar cell according to embodiments provided above comprises an ITO top contact layer, an n-type ZnO layer, a CdS buffer layer, and a p-type CIGS layer having a Mo metal contact. Due to the susceptibility of such a structure to deterioration via moisture, the CIGS-based solar array is preferably vapour and moisture sealed with a transparent and electrically insulating top covering an electrically insulating bottom layer in thermal contact with the rear metal contact.

Other photovoltaic array systems that may be employed with the present embodiments include those formed with monocrystalline silicon, polycrystaliline silicon, silicon, cadmium telluride, copper-induim selenide, copper indium gallium selenide, gallium arsenide, dye-sensitized cells, and polymer solar cells.

FIG. 6 illustrates an embodiment involving a multi-functional tandem-layer device 350. Device 350 comprises three multilayer planar structures spaced parallel to each other with a gap space between each pair of planar structures, and with the gap along the perimeter sealed so that the gap space can hold fluid with no leakage.

The top planar structure may include an external photocatalytic disinfectant layer 410 for self cleaning, and an anti-reflection multi-layer coating 420 to trap sunlight. These layers are provided onto a transparent substrate that is preferably glass, and two glass panes 430 and 450 with an internal vacuum layer 440. On the bottom surface of the lower glass pane 450 is an internal photocatalytic disinfectant layer 460 for disinfecting a working fluid (preferably water) flowing through the channel formed between the first and second planar structures.

The second planar structure comprises an upper transparent and electrically insulating layer 480 that is preferably glass. The structure then comprises a photovoltaic cell multilayer zone that preferably includes the following layers: a transmissive top contact layer 490 (preferably ITO), n-type ZnO 500, a CdS buffer layer 510, p-type CIGS 520, and a bottom metal contact layer 530 that is preferably Mo. The bottom metal contact layer is preferably attached to but electrically insulated from a thermally conductive heat sink or heat extraction layer (not shown). The heat sink itself may be electrically insulating, or the heat sink may be attached to the bottom metal contact through an insulating layer such as glass.

As shown by the arrows in the figure, cold working fluid from tank 400 is provided via line 360 to channel 470 between the first and second planar structures, where it is disinfected by the photocatalytic layer. The fluid in line 360 is relatively colder than the fluid in line 370 due to a thermal gradient within tank 400. The working fluid then flows to channel 540 between the second and third planar structures, where it is thermally contacted with the bottom surface 530 of the solar cell structure. The third planar structure comprises a bottom housing layer 550 that is preferably thermally insulating. Preferably, this bottom layer comprises a vacuum jacket layer that may be formed between two panes of glass. Heated working fluid is then passively transported by convective forces back to fluid tank 400 via line 370. Additional or replacement fluid may be provided to tank 400 using feed line 380, which is controlled by valve 390.

The functional layers of the hybrid device may be assembled in tandem and sealed in the housing. Supporting structures, such plastic stand-offs, may be utilized to achieve the necessary spacing between the layers. Additional supporting structures may be provided in the vacuum layers to prevent deformation of the panel.

Typically, a photovoltaic according to the preferred embodiment panel can convert approximately 20% of the solar energy to electricity and the 3-in-1 design of the present invention enables the capture and storage of a significant portion of the residual solar energy in the form of thermal energy (e.g. stored in the water tank). It is expected that in most moderately-sized embodiments that include a fluid tank (for example, those adapted for consumer use), the tank temperature will normally not exceed more than 60° C. The 3-in-1 design also aims to prevent any micro-organism growth in the tank. An additional synergetic benefit of the 3-in-1 design is that cooling the PV panel can increase its device efficiency and lifetime. Furthermore, the solar-electricity, when it is not used immediately, can be automatically converted to heat and stored in the tank. Hence, the inventive contribution and value of the 3-in-1 design is much more than the sum of the individual functional mechanisms.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

1. A hybrid solar energy conversion device comprising:
a housing having a transparent top layer;
a photovoltaic array enclosed within said housing, wherein light incident on and transmitted through said top layer illuminates said photovoltaic array for producing electricity and heat;
a first fluid conduit formed between said top layer and an upper surface of said photovoltaic array;
a photocatalyst provided within said first fluid conduit for treating a working fluid flowing in said first fluid conduit; and
a second fluid conduit provided beneath said array, said second fluid conduit in flow communication with said first fluid conduit, wherein said second fluid conduit is configured to provide thermal contact between said working fluid and said photovoltaic array for extracting heat from said photovoltaic array; and
an inlet port and an outlet port in flow communication with said first fluid conduit and said second fluid conduit.

2. The device according to claim 1 wherein said photocatalyst comprises a coating adhered to a light transmitting surface within said first fluid conduit.

3. The device according to claim 2 wherein said photocatalyst is adhered to at least a portion of an inner surface of said first fluid conduit.

4. The device according to claim 1 further comprising a heat sink affixed to a back side of said array, wherein said heat sink is positioned to contact said working fluid in said second fluid conduit.

5. The device according to claim 1 wherein said photocatalyst comprises nanoscale titania.

6. The device according to claim 5 wherein said photocatalyst comprises glass fibers coated with nanoscale titania.

7. The device according to claim 1 wherein said top layer comprises at least two vacuum sealed transparent panes.

8. The device according to claim 1 further comprising an additional photocatalyst disinfectant adhered to an external surface of said top layer for self cleaning.

9. The device according to claim 1 wherein a spectral bandwidth of said photocatalyst comprises at least a portion of the ultraviolet spectrum.

10. The device according to claim 1 wherein one or more surfaces of said top layer comprises an anti-reflective coating.

11. The device according to claim 1 wherein at least a portion of said housing is thermally insulated.

12. The device according to claim 1 wherein one or more of said photovoltaic arrays comprises monocrystalline silicon, polycrystalline silicon, silicon, cadmium telluride, copper-indium selenide, copper indium gallium selenide, gallium arsenide, dye-sensitized, polymer solar cells, and Cu(InₓGa₁₋ₓ)Se₂ (CIGS).

13. The device according to claim 1 wherein said working fluid comprises water.

14. The device according to claim 1 wherein said working fluid is a gas.

15. The device according to claim 14 wherein said gas is air.

16. The device according to claim 1 wherein said photocatalyst comprises a suspension of photocatalytic particles within said working fluid.

17. A hybrid solar energy conversion system comprising one or more of said hybrid solar energy conversion devices according to claim 1, wherein said devices are connected in series or in parallel.

18. A hybrid solar energy conversion system comprising a hybrid solar energy conversion device according to claim 14 and a fan for providing a flow of said gas through said device.

19. A hybrid solar energy conversion system comprising a hybrid solar energy conversion device according to claim 1, said system further comprising:
a vessel for storing said working fluid, wherein said vessel is external to said hybrid solar energy conversion device and said inlet port and said outlet port are in flow communication with said vessel;
wherein said system is configured to circulate said working fluid between said vessel and said device.

20. The system according to claim 19 further comprising:
an inlet line connecting said inlet port to a first location within said vessel; and
an outlet line connecting said outlet port to a second location within said vessel.

21. The system according to claim 20 wherein said first location is above said second location, and wherein said system is configured to circulate said working fluid under passive convection.

22. The system according to claim 19 further comprising a flow means for circulating said working fluid.

23. The system according to claim 22 wherein said flow means is a pump.

24. The system according to claim 19 further comprising a heat exchanger for extracting heat from said working fluid.

25. The system according to claim 19 further comprising a heat extraction means for extracting heat from said working fluid.

26. The system according to claim 25 wherein said heat extraction means is external to said housing.

27. The system according to claim 26 wherein said heat extraction means is a heat exchanger.

28. The system according to claim 19 wherein said device is oriented at an angle relative to a horizontal plane, and wherein said system is configured to circulate said working fluid by convection generated within said device.

29. The system according to claim 28 wherein said device is positioned adjacent to said vessel, and wherein said inlet port and said outlet port positioned at an upper position on said device and are connected to said vessel.

30. A hybrid solar energy conversion device comprising:
a housing having a transparent top layer;
a photovoltaic array enclosed within said housing, wherein light incident on and transmitted through said top layer illuminates said photovoltaic array and produces electricity and heat;
a first fluid conduit formed between said top layer and an upper surface of said photovoltaic array;
a photocatalyst provided within said first fluid conduit for disinfecting a working fluid flowing in said first fluid conduit; and
a second fluid conduit provided beneath said array, said second fluid conduit in flow communication with said first fluid conduit, wherein said second fluid conduit is configured to provide thermal contact between said working fluid and said photovoltaic array for extracting heat from said photovoltaic array; and
a heat exchanger for extracting heat from said working fluid.

31. A method of converting solar energy, said method comprising the steps of:
providing a hybrid solar energy conversion device according to claim 1;
flowing said working fluid into said inlet port;
extracting working fluid from said outlet port; and
extracting electrical energy from said device.

32. The method according to claim 31 further comprising the step of extracting heat from said working fluid.

33. The method according to claim 31 further comprising the step of controlling a conversion efficiency of said photovoltaic array by varying a property of said working fluid.

34. The method according to claim 33 wherein said property is varied in response to a measured temperature, wherein said measured temperature is related to an efficiency of said photovoltaic array.

35. The method according to claim 33 wherein said property is one or more of a flow rate of said working fluid and an initial temperature of said working fluid.
